(19) United States
(12) Patent Application Publication
(10) Pub. No.: US 2020/0411450 A1
(43) Pub. Date: Dec. 31, 2020

(54) GLASS SUBSTRATE AND DISPLAY DEVICE COMPRISING THE SAME

(71) Applicant: Corning Incorporated, Corning, NY (US)

(72) Inventors: John Steele Abbott, III, Elmira, NY (US); Takashi Atsumi, Shizuoka (JP); Ahdi El-Kahlout, Lexington, KY (US); Yoshiki Goto, Nagoya-shi (JP); Steven Francis Hoysan, Chattanooga, TN (US); Chien Yu Hsu, Taichung (TW); Shinichi Ii, Suita-city (JP); Kiat Chyai Kang, Painted Post, NY (US); Yoshiaki Kato, TOKYO (JP); Shawn Rachelle Markham, Harrodsburg, KY (US); Timothy John O'Driscoll, Poughkeepsie, NY (US); Christian Lucien Stauter, Shizuoka-ken (JP)

(21) Appl. No.: 16/870,300

(22) Filed: May 8, 2020

Related U.S. Application Data
(62) Division of application No. 15/543,030, filed on Jul. 12, 2017, now abandoned.
(60) Provisional application No. 62/103,411, filed on Jan. 14, 2015.

(51) Int. Cl. H01L 23/00; C03C 17/06; H01L 27/12; C03C 17/23; C03C 21/00; C03C 17/34; G02F 1/1333; H01L 21/48

(52) U.S. Cl. CPC H01L 23/562; C03C 17/06; H01L 27/1218; H01L 27/1262; C03C 17/23; C03B 17/064; C03C 17/3411; C03C 17/34; G02F 1/1333; H01L 21/4803; C03C 2218/328; C03C 21/002

(57) ABSTRACT

Disclosed herein are methods for making a thin film device and/or for reducing warp in a thin film device, the methods comprising applying at least one metal film to a convex surface of a glass substrate, wherein the glass substrate is substantially dome-shaped. Other methods disclosed include methods of determining the concavity of a glass sheet. The method includes determining the orientation of the concavity and measuring a magnitude of the edge lift of the sheet when the sheet is supported by a flat surface and acted upon by gravity. Thin film devices made according to these methods and display devices comprising such thin film devices are also disclosed herein.

### CROSS-REFERENCE TO RELATED APPLICATIONS

This application claims the benefit of priority under 35 U.S.C. § 119 of U.S. Provisional Application Ser. No. 62/103,411 filed on Jan. 14, 2015, the content of which is relied upon and incorporated herein by reference in its entirety.

### FIELD OF THE DISCLOSURE

The disclosure relates generally to glass sheets or substrates for display devices, and more particularly to glass sheets or substrates for thin film devices such as thin film transistors (TFTs) and high resolution flat panel display devices comprising the same. The disclosure also relates generally to methods for determining the conformability of a sheet of glass to a reference surface based on a concavity of a glass sheet, and identifying the concavity direction to facilitate the deposition of a thin film onto a surface of the sheet.

### BACKGROUND

Liquid crystal displays (LCDs) are commonly used in various electronics, such as cell phones, laptops, electronic tablets, televisions, and computer monitors. Increased demand for larger, high-resolution flat panel displays drives the need for large high-quality glass for use in the display, e.g., for use in manufacturing the TFT, color filter, or other display components. 4K2K or ultra-high definition displays may present a solution for balancing high resolution and cost-effectiveness in terms of product manufacture.

4K2K is used to refer to display devices with a horizontal resolution on the order of 4,000 pixels (industry standard 4096×21060 at a 1.9:1 aspect ratio). However, this large number of pixels can generate more resistive capacitance (RC), which can in turn impact the charging efficiency of the device. To reduce RC delay and increase pixel charging, it may be desirable to increase the width and/or thickness of the metal film deposited on the glass surface. For example, as illustrated in FIG. 1, the width W₂ and/or thickness T₂ of the metal film in a 4K2K device may be significantly larger than the width w₂ and/or thickness t₂ of the metal film in a full high definition (FHD) device. As shown in FIG. 2, the deposition of a thicker metal layer can result in warp due to film stress, which can give the thin film device a non-planar or bowl-like shape instead of a flat shape.

Further, the processing of glass sheets for electronic devices such as displays or lighting panels may require conforming the sheet to a planar support to form certain components of the device. These components, such as organic light emitting diode materials and other thin films, are typically formed via a photolithography process that includes vacuum chucking the sheet to a planar surface to flatten the sheet. The ability of the glass sheet to conform to the planar support depends on the intrinsic (e.g., gravity-free) shape of the sheet (e.g., the shape the sheet would have in the absence of gravity). Certain shapes, known as developable shapes, may be conformed to a plane relatively easily, resistance to conforming be largely a result of the stiffness of the sheet. On the other hand, non-developable shapes are not so easily flattened. Thus, certain shapes may introduce difficulty in the photolithography process. More importantly, the orientation of the shape relative to the planar support may impact the ability of the sheet to conform.

Accordingly, it would be advantageous to provide thin film devices, e.g., TFTs for large flat panel display devices such as LCDs which address one or more of the above drawbacks, e.g., flatter TFTs with lower cost and/or higher resolution. In various embodiments, LCD devices comprising such TFTs may provide improved picture quality, improved charging and/or energy efficiency, and/or improved cost efficiency.

### SUMMARY

The disclosure relates, in various embodiments, methods for making a thin film transistor and/or for reducing warp in a thin film transistor. The manufacture of thin film devices such as thin film transistors on glass substrates or sheets requires a surface having a high degree of flatness. This is so because the method of choice for producing the device comprises photolithography, and the depth of field for this optical process is usually very shallow.

As glass sheet is produced, the glass sheet may acquire warping, wherein the glass sheet exhibits a degree of concavity (i.e. curvature) so that the glass sheet will not lie perfectly flat on a supporting reference surface, even if vacuum chucked to the surface. In its simplest form this concavity can appear as a dome relative to the reference surface, or as a bowl relative to the reference surface.

It has been found that the degree of flatness that can be achieved by the glass sheet when the sheet is oriented as a dome relative to the reference surface is greater than the degree of flatness achievable if the glass sheet is oriented as a bowl relative to the reference surface. This occurs because the edge of a ‘bowl’ has no weight on it, and can curve upward, but the edge of a ‘dome’ touches the reference surface, supporting weight. Moreover, when the glass sheet is oriented as a bowl relative to the reference surface, and an attempt is made to flatten the sheet, edges of the sheet exhibit a tendency to lift from the supporting reference surface. This lifting can expose vacuum ports beneath the glass sheet and thereby affecting the ability of the vacuum to flatten the sheet. On the other hand, when the glass sheet is oriented as a dome relative to the supporting reference surface, the vacuum chucking has a tendency to curl the edges downward, toward the reference surface, thereby minimizing vacuum leakage. Thus, to provide the maximum flatness, orienting a glass sheet in a domed position on the supporting reference surface maximizes the achievable flatness, and improves the process of forming thin film devices on the glass sheet.

In one embodiment, a method of preparing a glass sheet for forming a thin film device is described comprising the steps of providing a glass sheet having opposing first and second sides, the sheet further comprising a concavity, supporting the glass sheet on a flat reference surface, determining an edge lift or warp of the glass sheet relative to the flat reference surface, determining an orientation of the glass sheet concavity based on a magnitude of the measured edge lift; and marking the sheet to indicate the orientation of the concavity. The orientation of the concavity may be determined by measuring a maximum edge lift. The maximum edge lift of the glass sheet is less than or equal to about 100 μm within 20 mm of an edge of the glass sheet. In other embodiments, the maximum edge lift is less than or equal to about 100 μm within 5 mm of the edge of the glass sheet. The orientation of the concavity may be determined by determining an average edge lift. The marking may comprise removing a corner of the glass sheet. The marking may comprise irradiating the glass sheet with a laser to produce a surface mark or a sub-surface mark. In one embodiment, the glass sheet is produced by a fusion downdraw process.

In another embodiment, a method of forming a thin film device is disclosed comprising supporting a glass sheet comprising a concavity on a flat reference surface in an orientation such that the glass sheet is dome shaped relative to the reference surface and depositing a thin film material on a dome side of the glass sheet. The method may further comprise removing a portion of the thin film material by photolithography. The thin film material may, for example, comprise a thin film transistor.

In still another embodiment, a thin film device comprising a glass sheet having a concavity is described wherein the thin film device is disposed on a dome side of the glass sheet when the glass sheet is supported by a flat reference surface. The thin film device may, for example, comprise a thin film transistor. In some embodiments, the thin film device does not exhibit an edge lift greater than 100 mm when vacuum chucked on the flat reference surface.

Additional methods include applying at least one metal film to a convex surface of a glass sheet or substrate with a substantially dome-shaped profile. Thin film transistors made according to these methods and display devices comprising such thin film transistors are also disclosed herein In certain embodiments the metal film can comprise a metal chosen from copper, silicon, amorphous silicon, polysilicon, ITO, IGZO, IZO, ZTO, zinc oxide, other metal oxides and doped metals and oxides thereof, and combinations thereof. According to additional embodiments, the glass sheet or substrate can have a thickness of less than about 3 mm, for example, ranging from about 0.2 mm to about 2 mm, from about 0.3 mm to about 2 mm, from about 0.7 mm to about 1.5 mm, from about 0.2 mm to about 0.5 mm, from about 0.3 mm to about 0.5 mm, from about 0.2 mm to about 1.0 mm, or from about 1.5 mm to about 2.5 mm, including all ranges and subranges therebetween. The glass sheet or substrate can be chosen, for example, from aluminosilicate, alkali-aluminosilicate, borosilicate, alkali-borosilicate, alum inoborosilicate, alkali-alum inoborosilicate, and other suitable glasses. In various embodiments, the glass sheet or substrate can be transparent or substantially transparent. It should be noted that the terms “sheet” and “substrate” as well as their respective plural terms are used interchangeably throughout this disclosure and such use should not be construed as limiting the scope of the claims appended herewith.

It is to be understood that both the foregoing general description and the following detailed description present various embodiments of the disclosure, and are intended to provide an overview or framework for understanding the nature and character of the claims. The accompanying drawings are included to provide a further understanding of the disclosure, and are incorporated into and constitute a part of this specification. The drawings illustrate various embodiments of the disclosure and together with the description serve to explain the principles and operations of the disclosure.

### BRIEF DESCRIPTION OF THE DRAWINGS

The following detailed description can be further understood when read in conjunction with the following drawings.

FIG. 1 illustrates exemplary TFTs for FHD and 4K2K display devices;

FIG. 2 illustrates TFT warp due to tension film stress in an exemplary display device;

FIG. 3 is a depiction of UV masking of a warped TFT;

FIGS. 4A-C are depictions of resist film coating of a warped TFT;

FIGS. 5A-B are depictions of warp measurement for a TFT;

FIGS. 6A-B depict sheet shape metrology tool data (e.g., BON data) for exemplary glass substrates;

FIG. 6C-D are graphical illustrations of TFT warp as a function of glass substrate shape;

FIG. 7 is a depiction of TFT warp reduction according to various embodiments of the disclosure;

FIG. 8 is a graphical illustration of TFT warp as a function of glass substrate shape;

FIG. 9A-B depict sheet shape metrology tool data (e.g., BON data) for exemplary glass substrates;

FIGS. 10A-D are graphical depictions of stress profiles and dome shape for various exemplary glass substrates;

FIG. 11 is a graphical depiction of stress profile and dome shape for various exemplary glass substrates;

FIG. 12 is a graphical depiction of TFT warp as a function of glass shape;

FIG. 13 is a partial cutaway view shown in perspective of an exemplary fusion downdraw apparatus for forming glass sheets;

FIG. 14 is a cross sectional side view of a laser sealing process for sealing an organic light emitting diode device;

FIG. 15 is a graphical perspective view representative of a glass sheet in a concave upward or dome shaped orientation with respect to a reference surface;

FIG. 16 is a graphical perspective view representative of a glass sheet in a concave down or bowl shaped orientation with respect to a reference surface;

FIG. 17 is a partial side view of an edge of a sheet of glass in a dome shaped orientation and chucked with respect to a reference surface in the presence of gravity;

FIG. 18 is a partial side view of an edge of a sheet of glass in a bowl shaped orientation and chucked with respect to a reference surface in the presence of gravity;

FIG. 19 is a plot of the predicted bare glass warp or edge lift for glass sheets with respect to the maximum gravity free shape deviation of the sheet for both bowl; shaped and dome shaped sheets;

FIG. 20 is a plot of predicted TFT warp or edge lift as a function of the tension applied by a thin silicon film deposited on the sheet for a variety of film thicknesses;

FIG. 21 is a top view of a sheet of glass that has been “marked” to show the proper support orientation by removing a corner of the sheet;

FIG. 22 is an edge view of a dome shaped sheet of glass comprising a thin film deposited on the domed side of the sheet; and

FIGS. 23A and 23B are plots of predicted TFT warp or edge lift as a function of the tension applied by a thin silicon film deposited on the sheet for a variety of sheet thicknesses.

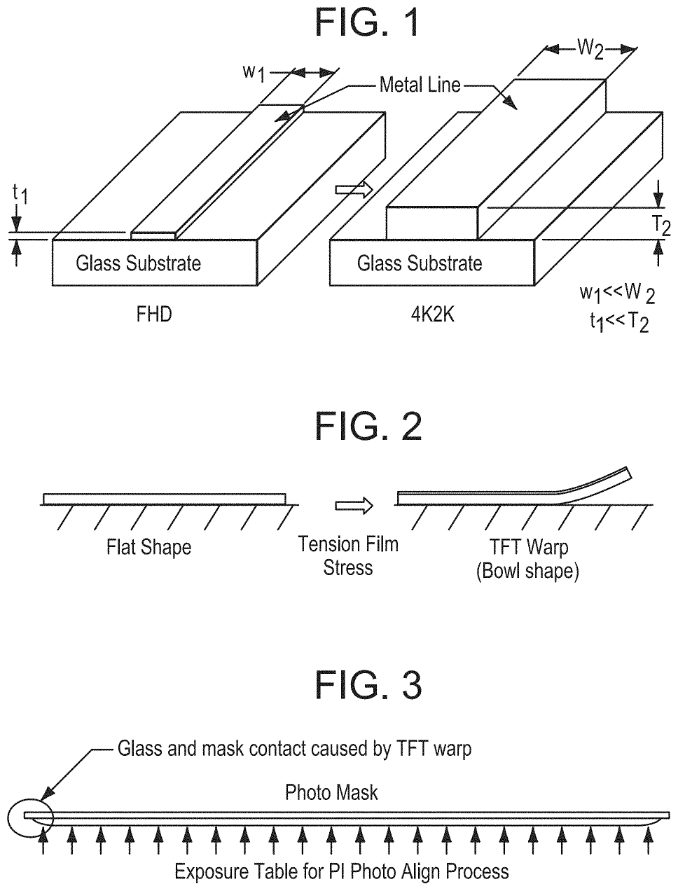

### DETAILED DESCRIPTION

Disclosed herein are methods for making a thin film device such as, but not limited to, a thin film transistor and/or for reducing warp in a thin film device, the methods comprising applying at least one metal film to a convex surface of a glass substrate, wherein the glass substrate is substantially dome-shaped. Thin film devices made according to these methods and display devices comprising such thin film devices are also disclosed herein.

One non-limiting method of manufacturing flat glass sheets is by the fusion downdraw method; however, the method can be any suitable glass sheet making process, including without limitation float processes, up draw, down draw, slot and fusion down draw processes. In an exemplary fusion downdraw process for forming glass ribbon, such as that illustrated in FIG. 13, a forming wedge 20 comprises an upwardly open channel 22 bounded on its longitudinal sides by wall portions 24, which terminate at their upper extent in opposed longitudinally-extending overflow lips or weirs 26. The weirs 26 communicate with opposed outer forming surfaces of wedge member 20. As shown, the wedge member 20 is provided with a pair of substantially vertical forming surface portions 28 which communicate with weirs 26, and a pair of downwardly inclined converging surface portions 30 that meet at lower apex or root 32.

Molten glass 34 is fed into channel 22 by means of delivery passage 36 communicating with channel 22. The feed into channel 22 may be single ended or, if desired, double ended. A pair of restricting dams 38 are provided above overflow weirs 26 adjacent each end of channel 22 to direct the overflow of molten glass 34 over overflow weirs 26 as separate streams, and down forming surfaces 28, 30 to root 32 where the separate streams, shown in chain lines, converge to form a ribbon of glass 42. Pulling rolls 44 are placed downstream of root 32 and are used to adjust the rate at which the formed ribbon of glass leaves the root.

The pulling rolls can be designed to contact the glass ribbon at its outer thickened edges. The glass edge portions which are contacted by the pulling rolls are later discarded from the sheet. As glass ribbon 42 travels down the drawing portion of the apparatus, the ribbon experiences intricate structural changes, not only in physical dimensions but also on a molecular level. The change from a thick liquid form at, for example, the root of the forming wedge, to a stiff ribbon of approximately one half millimeter or less of thickness is achieved by a carefully chosen temperature field or profile that delicately balances the mechanical and chemical requirements to complete the transformation from a liquid, or viscous state to a solid, or elastic state. At a point within the elastic temperature region, a robot (not shown) is secured to the ribbon, such as through the use of compliant suction cups, and the ribbon is cut at cut line 48 above the robot to form a glass sheet or pane 50. Glass sheet 50 is then loaded by the robot (not shown) onto a carrier for transport to downstream processes.

In spite of stringent manufacturing controls used by glass manufacturers to form flat glass sheets, such as by the above process, these sheets may deviate in shape from a perfect plane. For example, in the fusion process described above, the glass ribbon can be drawn from the forming wedge by the pulling rolls that contact only edge portions of the ribbon, providing opportunity for the central portion of the ribbon to warp. This warping may be caused by movement of the ribbon, or by the interplay of various thermal stresses that may manifest within the ribbon. For example, vibrations introduced into the ribbon by the downstream cutting process may propagate upward into the visco-elastic region of the ribbon, be frozen into the sheet, and manifest as deviations in the planarity of the elastic ribbon. Variations in temperature across the width and/or length of the ribbon may also lead to deviations in planarity. Indeed, stresses that are frozen into the ribbon may be partially relieved by warping when individual sheets of glass are cut from the ribbon, thus also resulting in a non-flat surface. In short, the shape of a sheet of glass cut from the ribbon is dependent upon the physical and thermal histories of the ribbon during the transition of the ribbon through the visco-elastic region, and those histories may vary. Moreover, large glass sheets cut from the drawn ribbon may themselves be cut into a plurality of smaller sheets. Each division may therefore result in a relief or redistribution of stress, and a subsequent shape change. Thus, while the resultant sheet may generally be considered flat, the sheet may in fact exhibit valleys and/or peaks across its surface that may interfere with flattening the sheet during subsequent processing. Such changes in stress and/or shape may be detrimental to processes which rely on dimensional stability, such as the deposition of components onto a substrate, such as various thin film layers used in the manufacture of liquid crystal displays or other devices. In some embodiments, the sheet can be formed so as to have a consistent and known shape. It is desirable therefore that a method be devised wherein the shape of a glass sheet or substrate may be accurately determined, and the information thus obtained used to modify the thermal history of the glass ribbon being drawn.

Exemplary glass sheets or substrates may comprise any glass known in the art for use as a thin film device substrate including, but not limited to, aluminosilicate, alkali-aluminosilicate, borosilicate, alkali-borosilicate, alum inoborosilicate, alkali-alum inoborosilicate, and other suitable glasses. In certain embodiments, the glass substrate or sheet may have a thickness of less than or equal to about 3 mm, for example, ranging from about 0.2 mm to about 2 mm, from about 0.3 mm to about 2 mm, from about 0.7 mm to about 1.5 mm, from about 0.2 mm to about 0.5 mm, from about 0.3 mm to about 0.5 mm, from about 0.2 mm to about 1.0 mm, or from about 1.5 mm to about 2.5 mm, including all ranges and subranges therebetween. In one embodiment, the glass substrate can comprise chemically strengthened glass such as Corning® Gorilla® glass from Corning Incorporated. Such chemically strengthened glass, for example, may be provided in accordance with U.S. Pat. Nos. 7,666,511, 4,483,700, and/or 5,674,790, which are incorporated herein by reference in their entireties. Corning® Willow™, Lotus™ and Corning® EAGLE XG® glasses from Corning Incorporated may also be suitable for use as the glass substrate in various embodiments. In additional embodiments, the glass substrate can comprise high transmission glass and/or low-Fe glass such as, but not limited to, Iris™ glasses from Corning Incorporated provided in accordance with U.S. Patent Application Nos. 62/026,264, 62/014,382, and Ser. No. 14/090,275, which are incorporated herein by reference in their entireties.

According to further aspects, the glass sheet or substrate can have a compressive stress greater than about 100 MPa and a depth of layer of compressive stress (DOL) greater than about 10 microns, for example, a compressive stress greater than about 500 MPa and a DOL greater than about 20 microns, or a compressive stress greater than about 700 MPa and a DOL greater than about 40 microns. The glass substrate can, in some embodiments, be treated, e.g., chemically strengthened and/or thermally tempered, to increase the strength of the glass and/or its resistance to breakage and/or scratching.

According to non-limiting aspects of the disclosure, chemical strengthening may be carried out by an ion exchange process. For instance, a glass sheet (e.g., aluminosilicate glass, alkali-alum inoborosilicate glass) may be made by fusion drawing and then chemically strengthened by immersing the glass sheet in a molten salt bath for a predetermined period of time. Ions within the glass sheet at or near the surface of the glass sheet are exchanged for larger metal ions, for example, from the salt bath. The temperature of the molten salt bath and treatment time period will vary; however, it is within the ability of one skilled in the art to determine the time and temperature according to the desired application. By way of non-limiting example, the temperature of the molten salt bath may range from about 430° C. to about 450° C. and the predetermined time period may range from about 4 to about 8 hours.

Without wishing to be bound by theory, it is believed that the incorporation of the larger ions into the glass strengthens the sheet by creating a compressive stress in a near surface region. A corresponding tensile stress is induced within a central region of the glass sheet to balance the compressive stress. The chemical strengthening process of Corning® Gorilla® glass can have a relatively high compressive stress (e.g., from about 700 MPa to about 730 MPa; and even capable of greater than 800 MPa) at a relatively high DOL (e.g., about 40 microns; and even capable of greater than 100 microns). Such glass can have a high retained strength and high resistance to scratch damage, high impact resistance, and/or high flexural strength as well as a substantially pristine surface.

The glass sheet or substrate can, in various embodiments, be transparent or substantially transparent. As used herein, the term “transparent” is intended to denote that the glass substrate, at a thickness of approximately 1 mm, has a transmission of greater than about 85% in the visible region of the spectrum (400-700 nm). For instance, an exemplary transparent glass substrate may have greater than about 85% transmittance in the visible light range, such as greater than about 90%, greater than about 95%, or greater than about 99% transmittance, including all ranges and subranges therebetween. According to various embodiments, the glass substrate may have a transmittance of less than about 50% in the visible region, such as less than about 45%, less than about 40%, less than about 35%, less than about 30%, less than about 25%, or less than about 20%, including all ranges and subranges therebetween. In certain embodiments, an exemplary glass substrate may have a transmittance of greater than about 50% in the ultraviolet (UV) region (100-400 nm), such as greater than about 55%, greater than about 60%, greater than about 65%, greater than about 70%, greater than about 75%, greater than about 80%, greater than about 85%, greater than about 90%, greater than about 95%, or greater than about 99% transmittance, including all ranges and subranges therebetween.

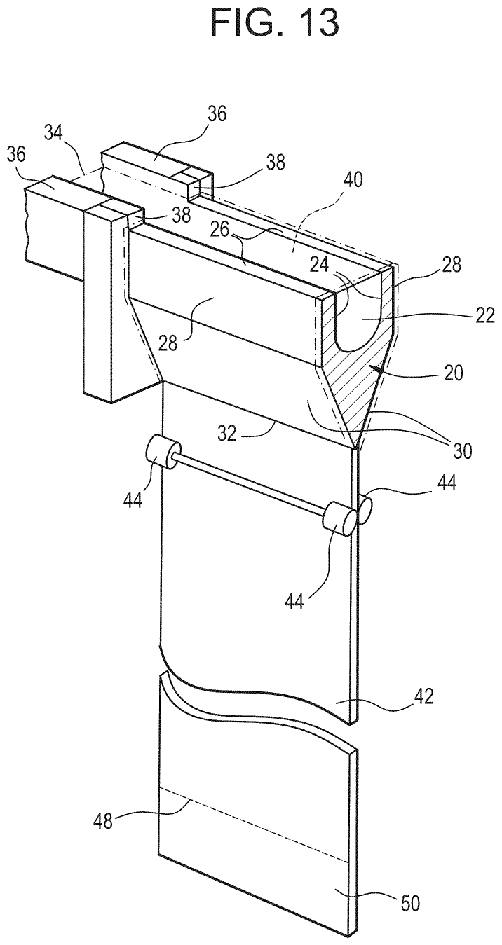

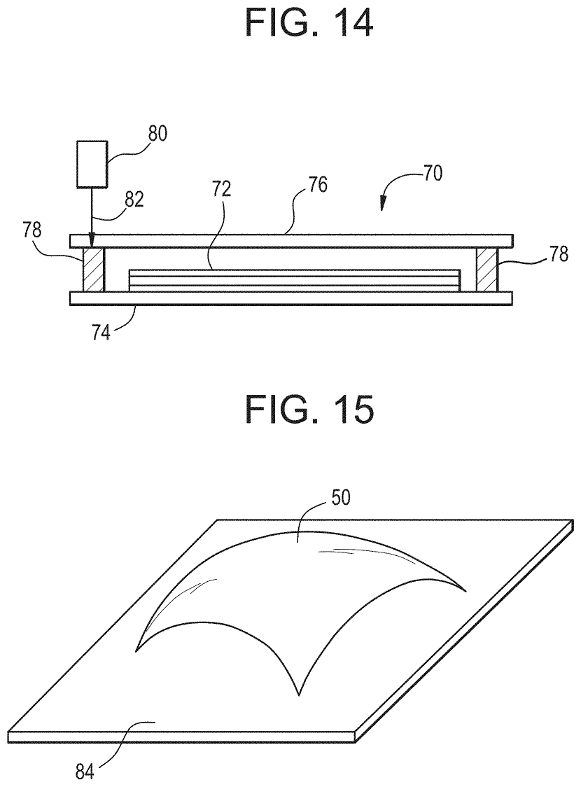

Device manufacturers can receive thin glass sheets produced by the glass manufacturer and further process the sheets to form a desired device such as a display panel, thin film device (e.g., thin film transistor (TFT), organic light emitting diode (OLED), color filter, or the like), or a solid state lighting panel (e.g., OLED lighting panel). For example, in the manufacture of a thin film device such as an organic light emitting diode device 70 shown in FIG. 14, an organic light emitting diode 72 is formed on a first glass sheet 74. This first glass sheet is often termed the backplane. The glass sheet or substrate may comprise a first surface and an opposing second surface. By way of a non-limiting example, the glass substrate may comprise a rectangular or square glass sheet having four edges, although other shapes and configurations are envisioned and are intended to fall within the scope of the disclosure. According to various embodiments, the glass substrate may have a substantially constant thickness across the length and width of the substrate. For example, the thickness may vary less than about 10% across the length and width of the substrate, such as less than about 5%, 3%, 2%, or 1%, including all ranges and subranges therebetween. In addition to organic light emitting materials, the light emitting diode on backplane 74 may also comprise TFTs and/or color filters and include electrodes for supplying an electric current to the organic materials and causing them to illuminate. However, because the organic materials are sensitive to various environmental factors, such as moisture and oxygen, the organic layers must be hermetically separated from the ambient environment. Thus, the organic layers may be sealed within a glass envelope formed by backplane 74, a second glass sheet or substrate 76, sometimes referred to as the cover sheet or cover plate and a sealing material 78 disposed between the backplane and the cover sheet and sealing. Several sealing methods may be used to connect the backplane to the cover plate, including the use of adhesives. While easy to apply and use, adhesives suffer from poor hermeticity needed to ensure the device exhibits a commercially viable lifetime before failure. That is, moisture and/or oxygen may eventually penetrate the adhesive seal, leading to a degradation of the organic layer(s), and the display device.

Another approach is to form a frit seal between the backplane and the cover sheet. Accordingly, a line of a glass frit paste sealing material can be dispensed over the cover plate in the form of a loop or frame, after which the fritted cover plate is heated to adhere the frit to the cover plate. The cover plate 76 is then positioned over backplane 74 with frit 78 (and the organic light emitting diode 72) positioned therebetween. Frit 78 is thereafter heated, such as with laser 80 emitting laser beam 82, to soften the frit and form a hermetic seal between backplane 74 and cover plate 76. It should be noted that thin film device 70 may take many forms, and the device of FIG. 14 is but one example. For example, the thin film device may comprise a liquid crystal device (e.g., a liquid crystal display), an organic light emitting lighting panel, or a myriad of other thin film devices known in the art. Moreover, the manner of sealing the device may vary depending upon the application. For example, the thin film device may be sealed with a conforming layer, such as a layer of inorganic material that is deposited by sputtering or evaporation or may be sealed using exemplary laser sealing or welding techniques described in co-pending U.S. application Ser. No. 14/271,797, filed May 7, 2014, the entirety of which is incorporated herein by reference.

Precise alignment of the is typically required during the device fabrication process, and particularly during the various processes for forming thin film devices. Typically, the glass sheets are required to be flat when forming components on the glass. For example, the backplane substrate is often vacuumed down onto a planar support surface for processing. During a photolithographic process for forming thin film devices (e.g., TFTs, color filters, OLEDs, etc.), the glass is held at the flattest possible horizontal plane. For example, the system depth of focus for a photolithographic process capable of depositing thin films on a Gen 7.5 glass substrate (1950×2250 mm) is approximately 20-30 microns. To achieve this capability, users of photolithographic equipment may employ a chucking table that enables large glass surfaces to be vacuum chucked. The surface flatness of such tables can be significantly less than 10 microns.

One metric used to characterize the flatness of a generally planar sheet of glass is a measure of the maximum “warp” of the glass. That is, the distance (or deviation) of a plurality of points on a surface of the sheet is determined with respect to a reference plane, and the deviation in distance from the reference represents the deviation of the sheet's shape from a true plane—the “warp” of the sheet. The maximum warp may be used as a measure of the shape of the sheet (e.g., flatness of the sheet).

The warp measurement just described yields only a simple representation of the topography of a glass sheet, and an indicator of one's ability to force the sheet flat, such as by vacuuming the sheet to a planar table. Whether the sheet shape is developable or not is another factor that may be considered. A developable surface is a surface that can be flattened without stretching, compression or tearing of the surface. Developable surfaces are surfaces that can be transformed into a plane surface while preserving angles and distances on the surface. When a developable surface is transformed into a planar surface, no strain is induced into the surface. Alternatively, a developable surface is a surface that may be formed from a planar surface without stretching, compressing, or tearing of the surface. Characterizing a sheet of glass via its maximum warp may be sufficient to indicate that the sheet is non-flat, but may be inadequate as a measure of how well the sheet may be forced into given configuration.

As described above, in a typical photolithography process the sheet to be processed can be forced against a support by ambient air pressure as a result of vacuum ports located across the surface of the support that reduce the pressure beneath the sheet. Moreover, when a vacuum is applied to the ports, the sheet is pressed against the support. The extent to which the force acting on the sheet is capable of conforming the sheet to the support surface is dependent, inter alia, on the distribution of the vacuum ports across the surface of the support. For example, a single, centrally located vacuum port would not be as effective as a large number of vacuum ports distributed across the surface of the support and beneath the sheet. Yet, even with such distributed porting, the distance between the ports may be insufficient to properly constrain the sheet. That is, for a glass sheet having a developable shape, if the ports are spaced too widely apart so that the distance between the edge of the sheet and the nearest vacuum port exceeds a certain distance, the edge of the sheet edge may lift as a result of strain induced into the sheet by the applied force.

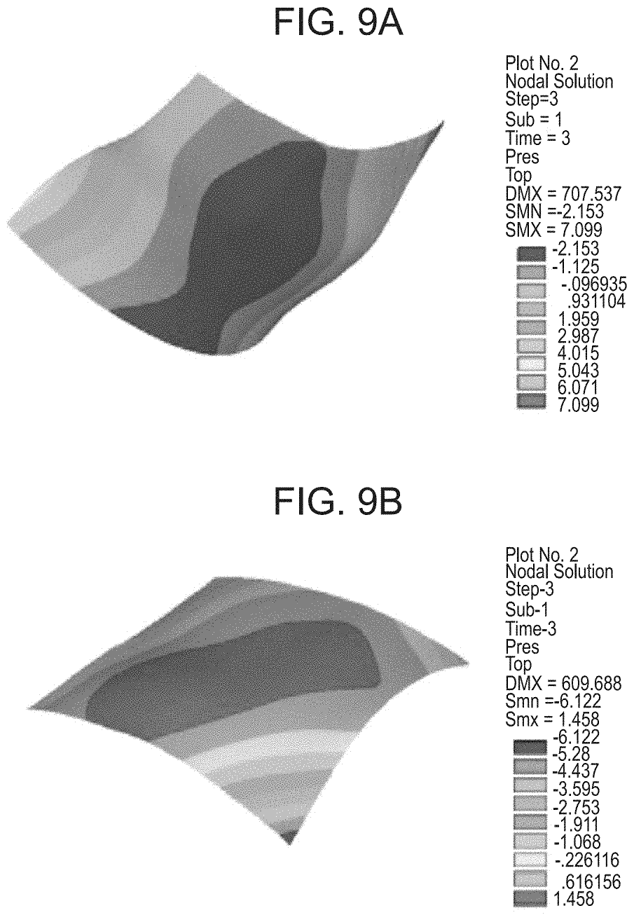

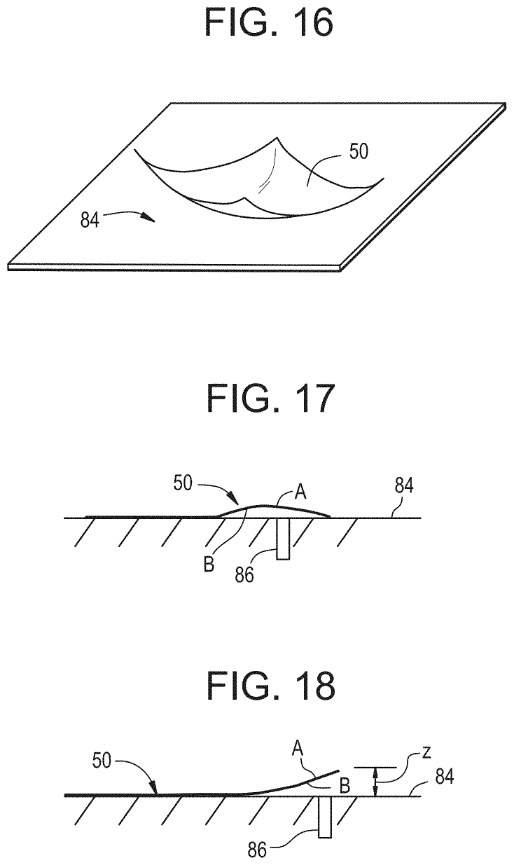

For a glass sheet that includes a concavity and is non-developable, the behavior of the edges of the sheet can be indicative of the orientation, or direction, of the concavity. As used herein, “concavity” is used generally to denote a dome shaped or a bowl shaped curvature in at least a portion of the sheet. Whether the concavity is considered a dome shape or a bowl shape depends on the orientation of the concavity with respect to a reference. Typically a dome is understood to be ‘convex’ and a bowl is understood to be ‘concave’. That is, a concavity viewed from one side of the sheet will appear as a dome, but would be a bowl when viewed from the opposite side (i.e., a bowl is an up-side down dome). For the purposes of this disclosure, the reference will be considered to be a planar support, whether that support is used in the context of a measurement, such as a measurement of the sheet warp (out of plane deviation), or in a subsequent processing step, such as a photolithography process. Thus, sheet 50 will be dome-shaped (concave down, bulge up) when the sheet is oriented relative to the support such that the bulge portion is away from reference surface 84, as shown in FIGS. 15 and 9B, or bowl-shaped (concave up, bulge down) when the sheet is oriented relative to the support such that the bulge is adjacent to reference surface 84, as shown in FIGS. 16 and 9A. For a dome shaped glass sheet, the dome side refers to the outward facing side of the sheet.

With continued reference to the gravity-free shapes in FIGS. 9A, 9B, 15 and 16, the glass sheet or substrate may be rounded and may have a constant curvature. The magnitude of curvature of the dome can vary as desired to achieve the appropriate resistance to warp. For instance, the height differential between a peripheral region of the glass substrate and a central region of the glass substrate can range from about 0.1 mm to about 20 mm, such as from about 1 mm to about 19 mm, from about 2 mm to about 15 mm, from about 3 mm to about 12 mm, from about 4 mm to about 11 mm, from about 5 mm to about 10 mm, from about 6 mm to about 9 mm, or from about 7 mm to about 8 mm, including all ranges and subranges therebetween. These large shapes up to 20 mm need to be understood as the gravity-free shape before flattening on a reference surface.

It should also be noted that the glass sheet or substrate comprises two major opposing surfaces that are substantially parallel to each other. When the glass sheet is supported by the reference surface, one surface (“B”) of the glass sheet will be adjacent to and in contact with the reference surface, whereas the other side (“A”) will be facing away from and therefore not in contact with the reference surface. For the purposes of the following description, the surface of the sheet that will be facing away from the support surface and therefore not in contact with the support surface is designated the “A” side of the sheet, whereas the surface or side of the sheet that will be in contact with the support surface is designated the “B” side of the sheet. Put another way, the “A” side of the sheet faces up when the sheet is place on a support and for a dome shaped sheet of glass supported by a reference surface, the dome side is the “A” side.

According to various embodiments, the A or B side of the glass substrate may be patterned with at least one metal film, such as strips or lines of metal film(s). In certain non-limiting embodiments, the metal film can be deposited on the convex surface of the glass substrate. According to various embodiments, the thickness and/or width of the metal film T₂ can range from about 1000 Å to about 10,000 Å, such as from about 2,000 Å to about 9,000 Å from about 3,000 Å to about 8,000 Å, from about 4,000 Å to about 7,000 Å, or from about 5,000 Å to about 6,000 Å, including all ranges and subranges therebetween. The metal film can comprise any metal suitable for use in a TFT or other thin film device, such as, for example, copper, silicon, amorphous silicon, polysilicon, ITO, IGZO, IZO, ZTO, zinc oxide, other metal oxides and doped metals and oxides thereof, and combinations thereof.

The metal film can be applied, e.g., deposited on the glass substrate according to known methods in the art. For instance, the film can be deposited at elevated temperatures ranging up to 1500° C., such as from about 500° C. to about 1250° C., or from about 750° C. to about 1000° C., and, subsequent to film deposition, the substrate can be allowed to cool to a second temperature of less than about 100° C., e.g., to room temperature. The substrate can then be further processed, e.g., treated with a UV mask, coated with a resist film, and other optional treatments known in the art.

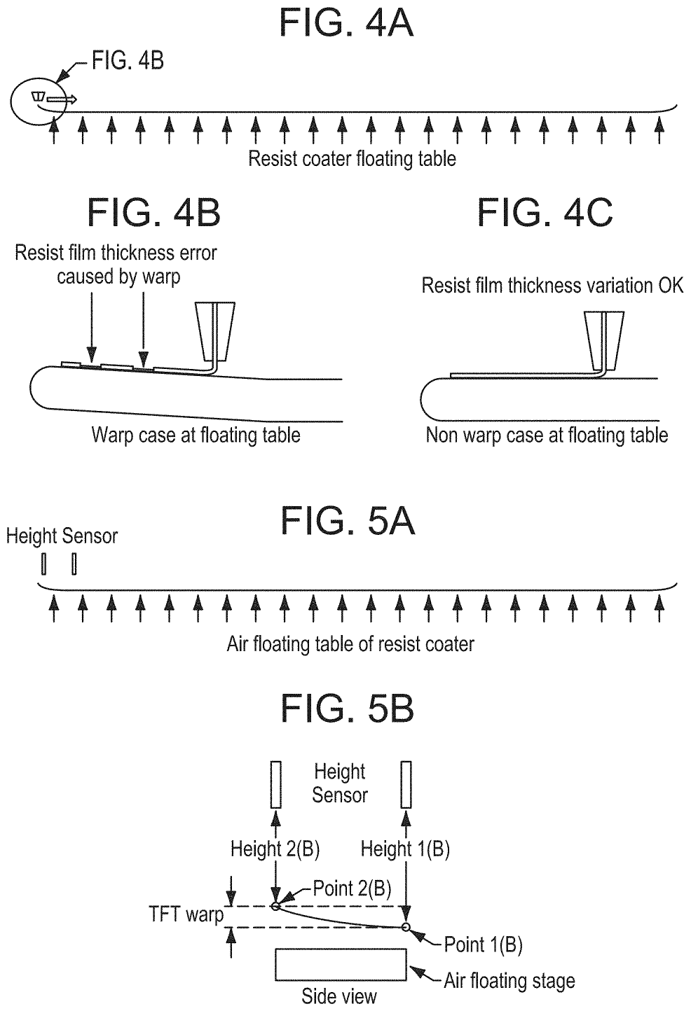

As shown in FIGS. 3 and 4A-C, warp can cause various processing complications, such as during a UV masking process due to contact between the warped regions of a thin film device and the mask during PI photoalignment process (FIG. 3) and/or during slit coating of a thin film device (e.g., illustrated as a TFT) due to an inhomogeneously applied resist layer, e.g., at different thicknesses, in warped regions of the TFT (FIGS. 4A-C). In some embodiments, warp can be measured, for instance, using height sensors installed at one or more points along the manufacturing process (e.g., the resist coater air floating table) and by subtracting the height of the thin film device at two measured points (e.g., Point 2-Point 1), as shown in FIGS. 5A-B. Warp caused by the applied metal film stress can be due to, e.g., tension in the film during cooling down to room temperature, such as from about 250° C. to about 25° C. Because the metal film can have a higher coefficient of thermal expansion (CTE) than the glass substrate, as the thin film device cools it can warp due to tension in the metal film which can cause the edges to curl upward to form a bowl-like shape. In some embodiments, film stress can be expressed as a factor of film CTE and Young's modulus, as expressed in the following formula (I):

$${σ}_{f} \approx \frac{( {α}_{f} - {α}_{g} ) {Δ}_{T} {E}_{f}}{1 - {v}_{f}} \qquad ( I )$$

where σ_{f} represents film stress, σ_{f} represents film CTE, σ_{g} represents glass CTE, ΔT represents the temperature difference during cooling (e.g., 250° C.-25° C.), E_{f} represents film modulus, and v_{f} represents the film Poisson ratio.

Warp can be calculated for a thin film device as a function of film thickness/stress and glass thickness/Young's modulus according to the following formulas (II) and (III), which assume the initial sheet is flat and that the stress is tensile:

$$\begin{matrix}w = \frac{3}{2} {L}_{lift}^{2} \frac{{σ}_{f} {t}_{f}}{{E}_{s} {t}_{s}^{2}} ( 1 - {v}_{s}^{2} ) & ( II ) \\ {L}_{lift}^{2} = \frac{{σ}_{f} {t}_{f}}{{ρ}_{s} g} & ( III )\end{matrix}$$

where w is warp, e.g., the height difference between Points 1 and 2 (see FIG. 5B), L_{lift} is the horizontal distance between Points 1 and 2, σ_{f} represents film stress, t_{f} represents film thickness, Eₛ represents glass Young's modulus, tₛ represents glass thickness, vₛ represents the glass Poisson ratio, ρₛ is the density of the glass, and g is gravity. Because the gate/signal metal film thickness for 4K2K TFTs can be larger than that for a FHD display, warping in the TFT can be much more pronounced, particularly as screen size increases.

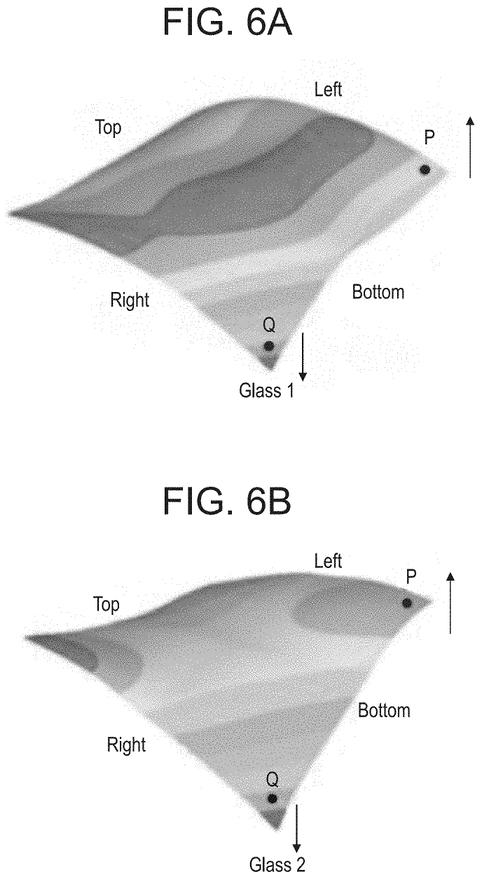

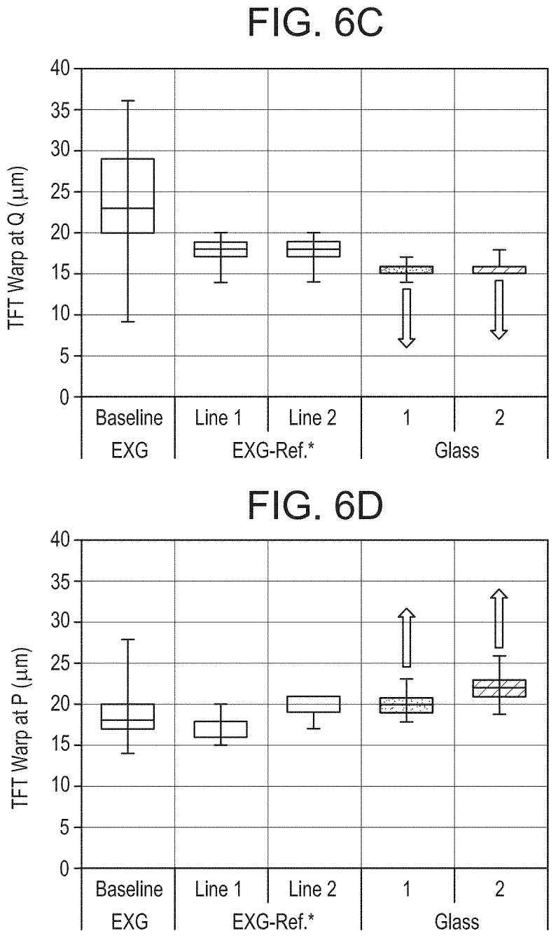

In view of formula (II) above, Applicant explored various methods for reducing or countering warp (w) including, for example, increasing the CTE of the glass, increasing the Young's modulus of the glass, increasing the thickness of the glass, and decreasing the warp of the glass. To determine the effect of glass CTE and Young's modulus as a countermeasure for warp, EAGLE XG® glass (CTE 32×10⁻⁷/° C., modulus 74 GPa) was compared to a comparative glass (CTE 34×10⁻⁷/° C., modulus 77 GPa). Based on formula (II) it was predicted that a TFT formed using the comparative glass would exhibit lower warp than a TFT made using the EAGLE XG® glass. However, it was observed that warp actually increased for the comparative glass as compared to EAGLE XG® glass at one position (Position P), whereas the reverse trend was observed for another position (Position Q) (see FIG. 6C).

Similarly, to determine the effect of glass thickness as a countermeasure for warp, TFTs made from EAGLE XG® glass substrates of different thicknesses (0.62, 0.63, 0.65 mm) were compared. Based on formula (II) it was predicted that a TFT formed using thicker glass would exhibit lower warp than a TFT made using thinner glass. However, no strong correlation was found to exist between warp and glass thickness. Finally, to determine the effect of bare glass warp as a countermeasure for TFT warp, TFTs made from EAGLE XG® glass substrates having different bare warp (ranging from 0.02-0.05 mm) were compared. Based on formula (II) it was predicted that a TFT formed using glass with lower bare warp would exhibit lower TFT warp than a TFT made using glass with a higher bare warp. However, no strong correlation was found to exist between TFT warp and glass warp, indicating that other factors have a stronger impact on TFT warp.

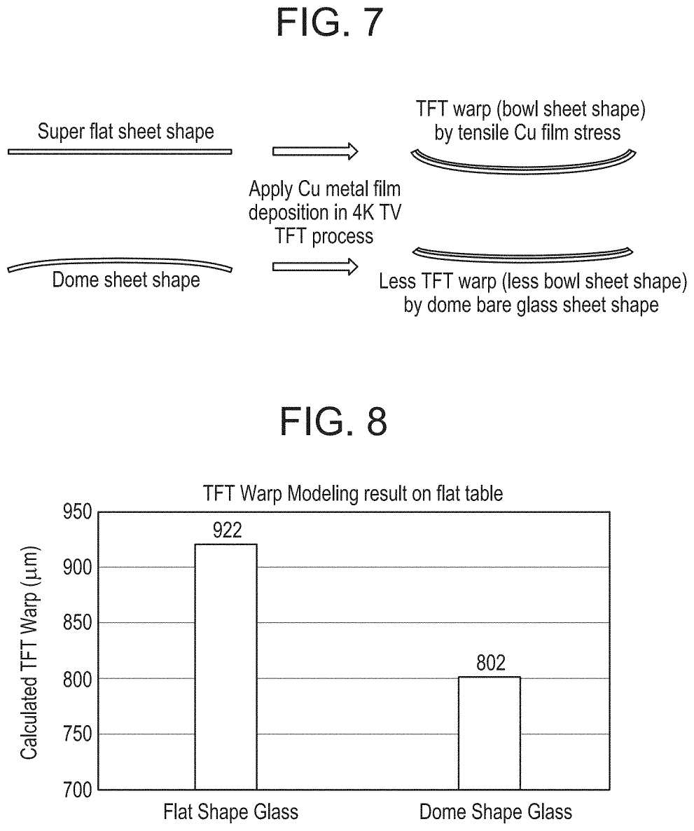

Applicant surprisingly discovered that thin film device warp can be counteracted by glass sheet shape, e.g., dome-shaped or convex glass substrates as discussed herein. Referring to FIGS. 6A-C, it was noted that comparative Glass 1 and Glass 2 exhibited low warp at position Q, whereas higher warp was observed at position P. Using sheet shape metrology tool data (e.g., Bed of Nail (BON) data) it was determined that the height of the glass sheet at position P was much higher than that of position Q for both glasses (Glass 1 ΔP−Q=−4.6; Glass 2 ΔP−Q=−9.2), e.g., the corner at position P was curved slightly upward (concave) and the corner at position Q was curved slightly downward (convex). Thus, without wishing to be bound by theory, it is believed that the “negative” shape of the glass at position Q (dome shape) was determined to counteract the warp caused by film tension stress, whereas the “positive” shape of the glass at position P (bowl shape) was determined to worsen the warp caused by film tension stress (see FIG. 7). Measurements taken for mass-produced EAGLE XG® glass confirm that warp was lower at position Q as compared to position P. Predictive modeling also confirms this correlation, as shown in FIG. 8.

Importantly, glass “shape” as used herein is to be distinguished from “warp” or “bare warp.” Warp measurements can be taken using known methods, such as full sheet warp (laser measures surface out of plane from known flat surface as supported on ball bearings of set spacing), or other horizontal gravity applied measurements; however, these methods do not accurately describe or show the full dome or bowl shape due to the impact of gravity. On the other hand, a sheet shape metrology (e.g., Bed of Nail (BON)) gauge coupled with mathematical modeling and further post-processing of the data, can allow engineers and scientists to look at what could be called intrinsic (e.g., gravity-free (or near gravity-free)) sheet shape as shown in FIGS. 9A-B.

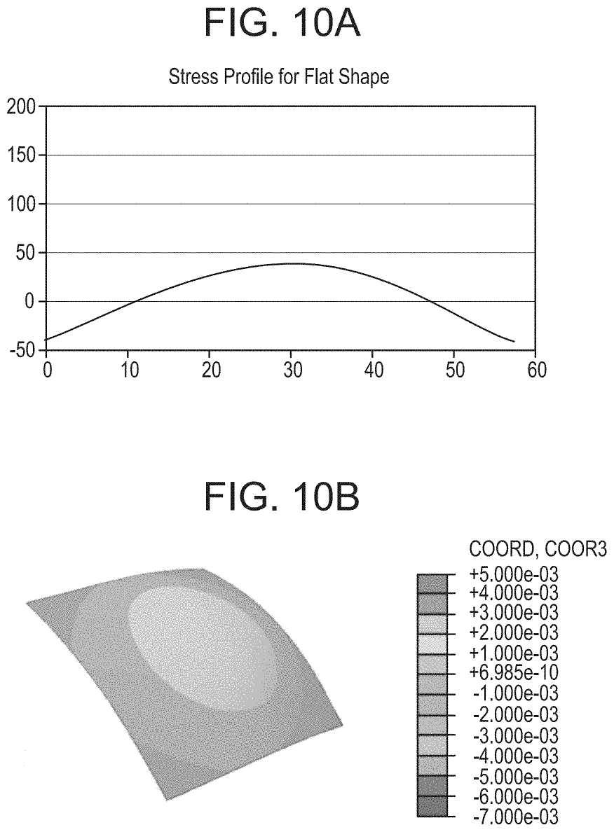

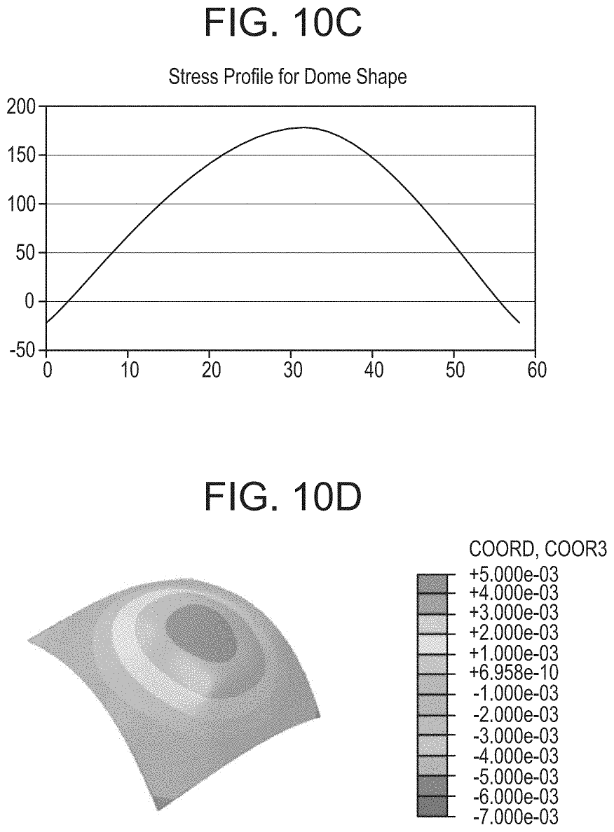

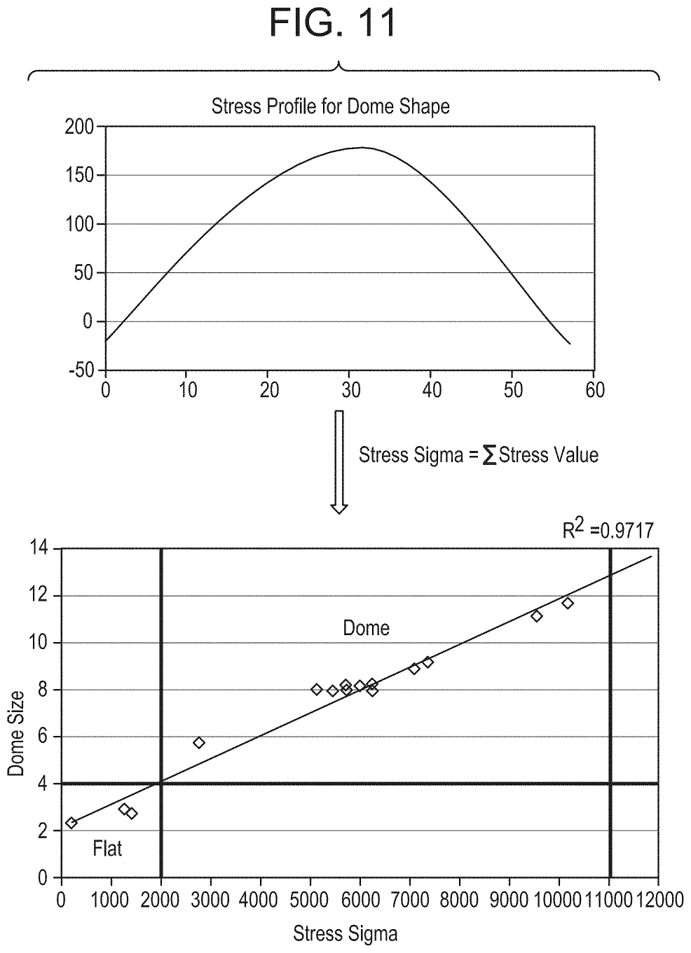

Glass substrates or sheets with a dome shape can be created using several methods as discussed above. In certain embodiments, it may be advantageous to create glass substrates with a substantially consistent shape and/or magnitude of dome curvature. The dome shape can, for example, be achieved as the glass is “set” from the molten state by adjusting the thermal profile and/or history, and/or by applying mechanical forces inside the glass forming machine. By way of a non-limiting example, the thermal profile in the glass viscoelastic setting zone can be adjusted to enhance the shape of the glass ribbon inside the forming machine, e.g., fusion draw machine (FDM). Additionally, the shape can be enhanced by physically contouring the glass ribbon using one or more contact rollers and/or wheels. Online and offline process measures and tools can be used to monitor glass shape during the forming and conditioning process. For example, online tools can include thermocouples for measuring temperature, glass shape monitoring cameras, and/or UV ray, ultrasound, and laser sheet sensors. Offline tools include, but are not limited to, gravity-impacted stress and warp measuring tools as well as gravity-free measurement and prediction tools. Mathematical simulations can be used to assist in the formation of the dome-shaped glass substrates. According to certain embodiments, measurement of the stress profile of the glass substrate can be used to confirm that the desired dome shape has been created, as illustrated in FIGS. 10A-D. Stress can be correlated to dome size as indicated by FIG. 11. When stress is measured by placing sheets horizontally on a flat surface, sheets with larger dome shape curvature will tend to have higher tensile stress. The stress field may be generated by the flattening of the sheet shape by gravitational forces.

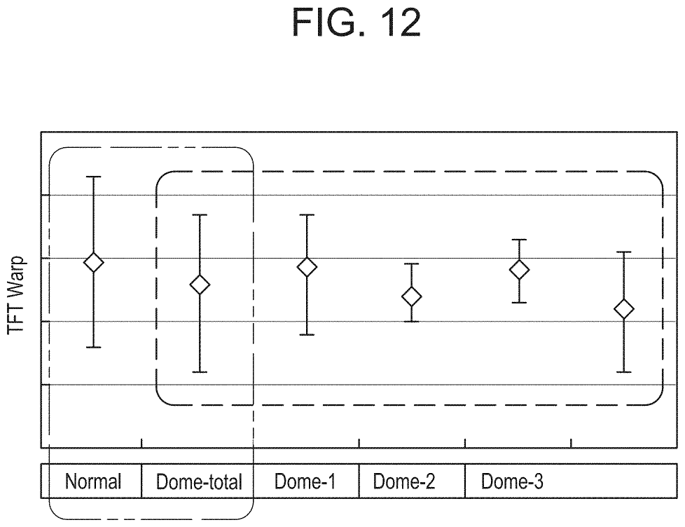

FIG. 12 further demonstrates that, as compared to “normal” glass substrates, domed glass substrates effectively provide reduced thin film device warp as a whole (as indicated by the Dome Total value). Furthermore, Domes 2 and 3 (higher curvature) exhibit markedly lower TFT warp as compared to Dome 1 (lower curvature).

It has also been found that the flatness of a glass sheet that is forced against a support surface, such as a flat vacuum table, is dependent on the orientation of the concavity relative to the support surface. That is, for the same vacuum applied, and the same general positioning of the sheet on the support, a dome-shaped sheet can be forced flatter than a bowl shaped sheet. Finite element analysis (FEA) was used to show that when a dome-shaped sheet is forced to conform to a generally planar surface, the edges of the sheet curl downward, as shown in FIG. 17. But, when a bowl-shaped sheet is supported in the same general manner, the edges of the sheet lift upward a finite distance “z”, as shown in FIG. 18. As used hereinafter, “z” will be referred to “lift”. Linear Elastic Plate (LEP) theory was also used to analyze the effects of curvature orientation, with similar results. The upward edge lift produced when an attempt is made to flatten a concave downward (bowl shaped) sheet on a vacuum table, such as that shown in FIG. 18, can result in a vacuum leak beneath the sheet, allowing a direct path between one or more vacuum ports and the ambient atmosphere. That is, the sheet (e.g., sheet 50) does not cover vacuum port 86. This vacuum leak can prevent further flattening of the sheet and affect the ability to form a thin film device on the sheet. To further explain FIGS. 17 and 18 for clarity, these diagrams apply to very thin glass sheets which are nearly flat. For example, in FIG. 17 the sheet is too large and/or the glass is so thin that it cannot support its own weight, and collapses flat in the middle of the sheet leaving a small elevated ‘ring’ near the edge. Likewise, in FIG. 18 the sheet cannot support its own weight until most of the interior is flattened so that only the weight of the thin edge region rises above the reference surface.

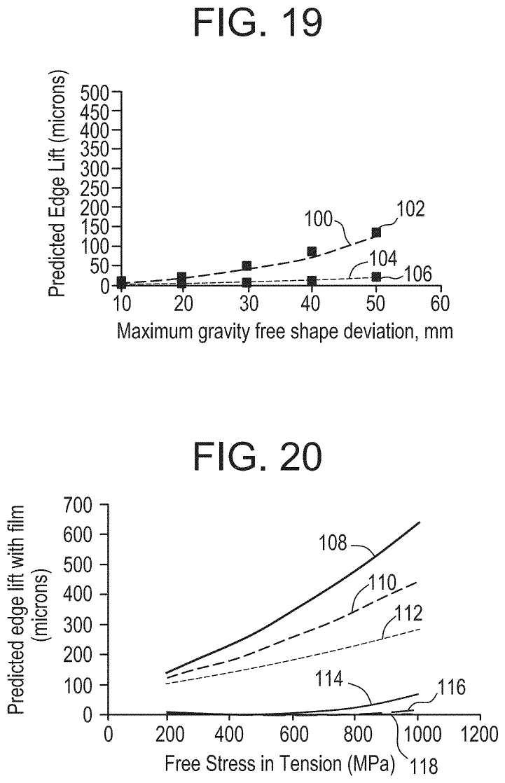

FIG. 19 depicts the modeled behavior of glass sheets having a known gravity-free shape (the shape the sheet would have in a gravity free environment). FEA and LEP analysis was used to predict the edge lift in microns that would occur given a maximum gravity free sheet shape in millimeters (the maximum vertical—or peak to valley—deviation of the sheet) when a gravitational load was placed on the sheets against a reference surface. The gravitational load simulated the effect of placing the sheet on a support and the role gravity would play in flattening the sheet. The results were plotted with the modeled edge lift on the vertical axis and the maximum overall sheet deviation along the bottom or horizontal axis.

In FIG. 19 there is good agreement between the predicted edge lift when modeled either by LEP or FEA analysis. Curve 100 and data points 102 represent the results of FEA (dashed line 100) and LEP (squares 102) analysis for a bowl shaped sheet, whereas curve 104 and data points 106 represent the results of FEA (dashed line 104) and LEP (squares 106) analysis for a dome shaped sheet. The data also show significantly more edge lift for a bowl shaped sheet of glass than the warp for a dome shaped sheet of glass given the same overall sheet shape.

The edge lifting effect described above can be exacerbated by thin films that may be deposited on a bowl shaped “A” (up) side during downstream processing. FIG. 20 illustrates the predicted edge lift of bowl and dome shape glass sheets when a deposited film (e.g., a silicon film) is deposited on the glass sheet and the film is in tension. Three film thicknesses were modeled for a glass sheet having a nominal thickness of about 0.7 mm. It was assumed the sheet had a gravity free warp (maximum deviation) of 30 mm. The effects were determined for a film applied both to the “A” or up side of a bowl shaped sheet (curves 108, 110 and 112 at a thickness of 4000 angstroms, 3000 angstroms and 2000 angstroms, respectively) and when the film is applied to the “A” side of a dome shaped sheet (curves 114, 116 and 118 at a thickness of 4000 angstroms, 3000 angstroms and 2000 angstroms, respectively). The results indicate that the edges of a bowl shaped sheet will lift significantly when applied with the thin film in tension, while a negligible effect was seen at the edges when the film was applied on dome shaped sheets. For a film in compression, the difference between edge curling on both bowl and dome shaped sheets is negligible.

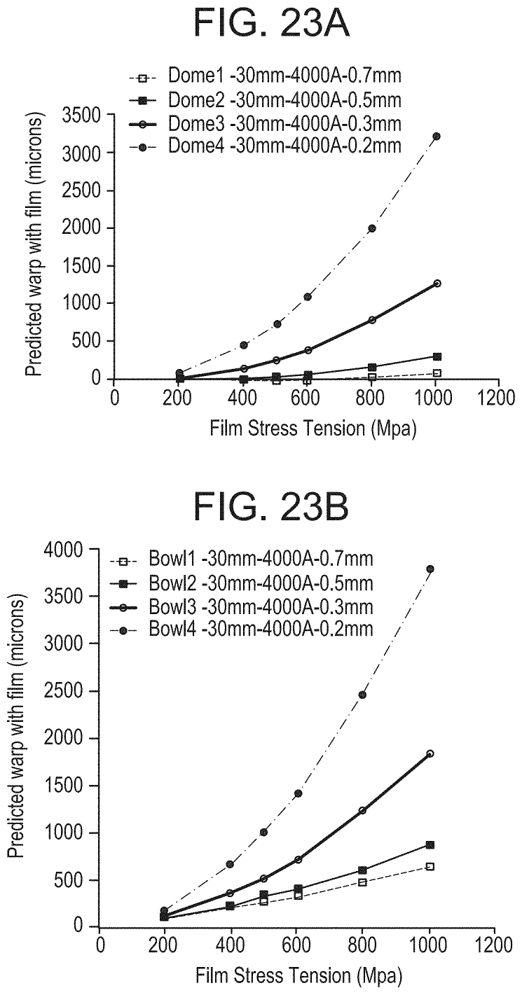

FIGS. 23A and 23B are plots of predicted TFT warp or edge lift as a function of the tension applied by a thin silicon film deposited on the sheet for a variety of sheet thicknesses. With reference to FIGS. 23A and 23B, the edge lifting effect described above can be affected by the thickness of the glass sheet, as indicated by equations I, II, III. A film tension will make a flat sheet more “bowl-like”, and if the sheet is already a bowl the film tension adds to this and the effect is as if the bowl were aggravated. If, however, the sheet is dome-shaped the film tension adds a bowl effect to the dome making it a smaller dome (i.e., flatter). FIGS. 23A and 23B illustrate plots of warp with film as the film tension increases for sheets of thickness of 0.7 mm, 0.5 mm, 0.3 mm, and 0.2 mm with a substantially constant 30 mm radius of curvature as shown in FIG. 20. As can be observed in these figures, the thickness decreases, and the warp increases for both bowl and dome. Further, it can be observed that if the thickness decreases enough, the film stress dominates and both dome and bowl show large warps, but the dome warp can be smaller than the bowl warp.

In accordance with an embodiment of the present disclosure, a glass sheet can be formed via a glass sheet forming process. The process may be any conventional or future glass sheet making process, including without limitation float processes, up draw, down draw, slot and fusion down draw processes.

In a first step, a glass sheet is transported from the forming apparatus to a measurement apparatus. In part because glass sheet used in the manufacture of some devices, such as liquid crystal display devices, is exceptionally thin (less than about 1 mm, between 0.2 mm or 0.3 mm and 0.5 mm, between 0.2 mm or 0.3 mm and less than 1 mm), and easily broken, such transport is typically carried out by automated equipment, such as “robots” that are computer/processor controlled. Robots are well known in manufacturing throughout the world, and will not be described further here, except to say that for the transport of glass sheet products, and especially glass sheet products intended for the subsequent manufacture of display products, every effort is made to minimize contact between the robot and the glass sheet that may mar or damage the surface of the sheet. Consequently, methods for temporarily connecting the robot to the glass sheet typically include pliant suction cups, air bearings, or a combination thereof.

In a following step the glass sheet is placed on a support surface to determine a topographical shape of the sheet. For purposes of discussion and not limitation, the measurement apparatus may be a sheet warp measurement. In a typical warp measurement a measurement table consisting of a large, flat, dimensionally stable platform is used to support the sheet. Suitable platforms include marble or granite slabs, or metal blocks, although the stone slabs are also suitable. The platform may further be vibration isolated using conventional vibration isolation legs. In one embodiment, an optical range finding device is attached to a gantry so that the range finding device can be moved above the surface of the glass sheet in a plane parallel to the surface of the platform. The range finding device is capable of determining a distance between the device and a surface of the glass sheet, generally the surface facing the range finding device. In turn, the gantry is capable of positioning the range finding device at a plurality of points over the surface of the glass sheet such that the range finding device can determine a distance between the device and the sheet over a plurality of points on the glass surface. Given a known distance between the range finding device and the platform surface supporting the glass sheet, the height of the measured surface of the sheet above the platform surface can be easily determined.

Typically, the glass sheet is a rectangle, and the measurement locations on the sheet can be arranged in a rectangular grid. However, other arrangements are also possible, depending on the shape of the glass sheet.

To ensure edge lift can be detected, the warp measurements should be taken within at least about 20 mm of each edge of the sheet, within at least about 10 mm of each edge, or within about 5 mm of each edge. If the edges of the sheet exhibit an edge lift of more than a predetermined limit above the plane of the reference surface supporting the sheet, the glass sheet may be determined to exhibit a bowl shape relative to the reference surface. For example, a value of about 100 μm has been found to be a suitable limit for edge lift. Conversely, if the edges of the sheet exhibit less than the predetermined amount of lift, the sheet may be considered to have a dome shape relative to the reference surface.

Several additional approaches can be used to determine the concavity of the glass sheet. As described above, if the sheet is bowl shaped, the edges will ‘lift off’ a horizontal support (reference) surface near the edge and the magnitude of this lift can be linked to the radius of curvature of the sheet. If z(x,y) is the height of the sheet from the horizontal reference, the maximum lift, z_max, along the edge and the average lift, z_ave, along the edge are determined. If one or both of z_max, or z_ave exceeds a predetermined threshold for each metric, it can be concluded the edge is lifted upward and the sheet has a bowl shape relative to the reference surface. The predetermined thresholds are dependent on the end use of the glass, customer specifications, and so forth. To determine that the edge is instead curled downward (e.g., the sheet is dome shaped) the sheet can be flipped over and measured again. It has been observed that the maximum lift is typically 7 times larger when the sheet is bowl shaped. To summarize, either the maximum lift seen along the edge or the average lift seen along the edge can be used to evaluate the orientation of the sheet. If all four edges of the sheet show a lift greater than 100 um, a bowl-like curvature has been identified.

Another method for determining a suitable orientation metric from the measurement data is to evaluate the slope or gradient of the sheet shape at or near the edge. If z(x,y) is the height of the sheet from a horizontal reference surface and “x” is the direction normal to the edge, then the gradient dz/dx at the edge of the sheet can also be used, either to supplement z_max and z_ave or as an alternative. The gradient may be a maximum gradient for each edge or an average gradient for each edge.

The measurement methods described above assume a simple bowl or dome shape to the sheet. However, the methods described herein can be extended to more complex sheet shapes. These include, for example, sheets where an edge is wavy, and the curvature along the edge is both concave and convex (e.g., serpentine). In this case merely flipping the sheet may not help. The metric (e.g., maximum lift, average lift, etc.) can be used to assess the suitability of the sheet for use, or to direct process work to eliminate the root cause from the sheet manufacturing process.

In other cases, the sheets may have some edges that exhibit a concave curvature and others that do not. In the manufacture of large glass sheets manufactured by the fusion process, two sides are vertical and two are horizontal as the sheet is drawn and cut from the ribbon. If the vertical edges are consistently concave using the metrics discussed above, and the horizontal edges are consistently convex, then the sheet can be presumed to be “saddle-shaped” and not simply bowl or dome shaped. In this case, some incremental improvement can be expected if the curvatures of the sheet can be adjusted via the sheet manufacturing process to achieve a dome-like shape in the sheet.

Glass sheets that are determined to exhibit a bowl shape when supported by their contacted side (that is, the side contacted by the robot, by a measurement support, etc.) may be rejected from the manufacturing process, and may end up as cullet that is recycled into the glass forming process, being re-melted with other feed materials. Alternatively, for some applications the sheet may be flipped to present the opposite side upward, and if the edge lift is within acceptable limits, the sheet is marked to indicate the proper (concave upward) orientation. Whether the sheet may be utilized when flipped is dependent on the end use requirements. On the other hand, glass sheets that have been determined to exhibit a dome shape when supported by the previously contacted side represent acceptable glass and may be marked accordingly for downstream processing. This is relevant because end users of the sheet typically tune their equipment (e.g., photolithographic equipment) to the behavior of the product they receive. Thus, it is important that they receive product that is oriented appropriately to maximize the success of a particular process step, but that the product is marked to indicate the proper orientation.

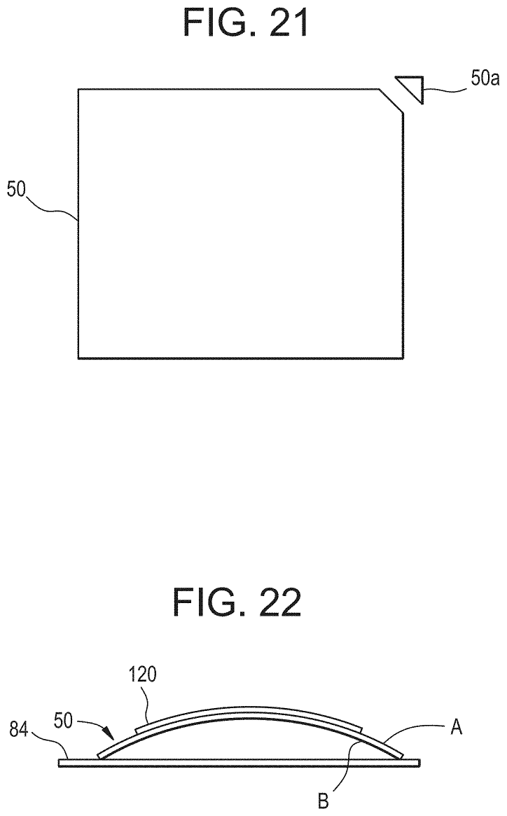

One such method of marking is to remove a small amount of material (50a) from a corner of sheet 50, a depiction of which is shown in FIG. 21. Thus, when the sheet is positioned in a predetermined orientation, i.e. with the modified corner positioned in a predetermined location, the appropriate surface of the glass sheet is supported and the concavity is dome-shaped relative to the support surface. Other methods may also be used as appropriate or available, such as surface or subsurface marking with a laser.

Once the proper orientation of the sheet has been determined, the sheet may be further processed. For example, by employing the marked orientation, the sheet is positioned on a chucking table (support) in a concave upward (dome) position and the sheet is flattened. For example, a vacuum may be applied through orifices in the table to flatten the sheet. Then, one or more thin film material layers can be deposited on the sheet. The one or more thin film layers may include insulating materials, dielectric materials, semiconductor materials or conducting materials. The thin film materials may be deposited by any suitable conventional method. For example, the thin film layers may be evaporated, co-evaporated or sputtered. FIG. 22 depicts a dome shaped glass sheet 50 comprising a thin film device 120 disposed on the up “A” side of the sheet. Once the appropriate layers of materials have been deposited, the material may be removed, such as by a photolithography process, to produce the desired device. The thin film deposition and material removal may be performed through multiple steps. This additional processing may be carried out by downstream “original equipment manufacturers”, who will transform the bare glass into a device such as a liquid crystal display, an organic light emitting diode (OLED) display or any other device by depositing additional films and components on the glass. Typically, many devices are formed on a single sheet of glass. Once the devices are formed, the sheet is thereafter separated into individual devices, such as device 70 of FIG. 14.

Thin film devices (e.g., TFTs, OLEDs, color filters, and the like) prepared according to the methods disclosed herein may have less warp as compared to thin film devices prepared using conventional flat glass substrates. In some embodiments, the thin film devices disclosed herein can have a warp that is at least about 20% less as compared to warp in similarly prepared thin film devices using flat glass substrates, such as at least about 30% less, at least about 40% less, at least about 50% less, at least about 60% less, at least about 70% less, at least about 80% less, or at least about 90% less, including all ranges and subranges therebetween. For instance, in various embodiments, the warp of the thin film device may be less than about 1000 microns, such as less than about 900 microns, less than about 800 microns, less than about 700 microns, less than about 600 microns, less than about 500 microns, less than about 400 microns, less than about 300 microns, less than about 200 microns, or less than about 100 microns, including all ranges and subranges therebetween. Display devices, such as LCDs, comprising such TFTs are also disclosed herein and may provide one or more advantages such as improved picture quality, improved charging and/or energy efficiency, and/or improved cost efficiency. However, it is to be understood that the thin film devices and display devices according to the present disclosure may not exhibit one or more of the above improvements, but are still intended to fall within the scope of the disclosure.

It will be appreciated that the various disclosed embodiments may involve particular features, elements or steps that are described in connection with that particular embodiment. It will also be appreciated that a particular feature, element or step, although described in relation to one particular embodiment, may be interchanged or combined with alternate embodiments in various non-illustrated combinations or permutations.

It is also to be understood that, as used herein the terms “the,” “a,” or “an,” mean “at least one,” and should not be limited to “only one” unless explicitly indicated to the contrary. Thus, for example, reference to “a metal film” includes examples having two or more such metal films unless the context indicates otherwise. Likewise, a “plurality” is intended to denote “more than one.” As such, a “plurality of metal films” includes two or more such films, such as three or more such films, etc.

Ranges can be expressed herein as from “about” one particular value, and/or to “about” another particular value. When such a range is expressed, examples include from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, as defined above, “substantially similar” is intended to denote that two values are equal or approximately equal. In some embodiments, “substantially similar” may denote values within about 10% of each other, such as within about 5% of each other, or within about 2% of each other.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to a device that comprises A+B+C include embodiments where a device consists of A+B+C and embodiments where a device consists essentially of A+B+C.

It will be apparent to those skilled in the art that various modifications and variations can be made to the present disclosure without departing from the spirit and scope of the disclosure. Since modifications combinations, sub-combinations and variations of the disclosed embodiments incorporating the spirit and substance of the disclosure may occur to persons skilled in the art, the disclosure should be construed to include everything within the scope of the appended claims and their equivalents.

1. A method for making a thin film device, comprising applying at least one metal film to a convex surface of a glass substrate at a first temperature to form the thin film device, and cooling the thin film device to a second temperature.

2. The method of claim 1, wherein the at least one metal film is chosen from copper, silicon, amorphous silicon, polysilicon, ITO, IGZO, IZO, ZTO, zinc oxide, other metal oxides and doped metals and oxides thereof, and combinations thereof.

3. The method of claim 1, wherein the at least one metal film has a thickness ranging from about 1,000 Å to about 10,000 Å.

4. The method of claim 1, wherein the at least one metal film has a width ranging from about 1,000 Å to about 10,000 Å.

5. The method of claim 1, wherein the glass substrate has a thickness of less than about 3 mm.

6. The method of claim 1, wherein the glass substrate has a thickness of between 0.2 mm and less than about 1 mm.

7. The method of claim 1, wherein the glass substrate is substantially dome-shaped or bowl-shaped.

8. The method of claim 1, wherein the glass substrate has a substantially constant thickness over a length and width of the glass substrate.

9. The method of claim 1, wherein the first temperature is less than about 1500° C. and wherein the second temperature is less than about 100° C.

10. The method of claim 1, wherein the at least one metal film and the glass substrate have different coefficients of thermal expansion over a temperature ranging from the first temperature to the second temperature.

11. A thin film transistor, color filter, or organic light emitting diode made according to the method of claim 1.

12. A method for reducing warp in a thin film device, comprising applying at least one metal film to a convex surface of a glass substrate, wherein the glass substrate is a substantially dome-shaped or bowl-shaped.

13. The method of claim 12, wherein the at least one metal film has a thickness ranging from about 1,000 Å to about 10,000 Å.

14. The method of claim 12, wherein the at least one metal film has a width ranging from about 1,000 Å to about 10,000 Å.

15. The method of claim 12, wherein the glass substrate has a substantially constant thickness over a length and width of the glass substrate.

16-27. (canceled)

28. A method of preparing a glass sheet for forming a thin film thereon comprising:
providing a glass sheet having a thickness between 0.2 mm and 1 mm comprising a concavity;
supporting the glass sheet on a flat reference surface;
determining an edge lift z of the glass sheet relative to the flat reference surface;
determining an orientation of the glass sheet concavity based on a magnitude of the measured edge lift; and
marking the sheet to indicate the orientation of the concavity.

29. The method according to claim 28, wherein a maximum edge lift is less than or equal to 100 μm within 20 mm of an edge of the glass sheet.

30. The method according to claim 28, wherein a maximum edge lift is less than or equal to 100 μm within 5 mm of an edge of the glass sheet.

31. The method according to claim 28, wherein the determining the edge lift comprises determining a maximum edge lift.

32. The method according to claim 28, wherein the determining the edge lift comprises determining an average edge lift.

33. The method according to claim 28, wherein the marking comprises removing a corner of the glass sheet.

34. The method according to claim 28, wherein the marking comprises irradiating the glass sheet with a laser.

35. The method according to claim 28, wherein providing the glass sheet comprises forming the glass sheet by a fusion downdraw process.

36. A method of forming a thin film device comprising:
supporting a glass sheet having a thickness between 0.2 mm and about 1.0 mm comprising a concavity on a flat reference surface in an orientation such that the glass sheet is dome shaped relative to the flat reference surface; and
depositing a thin film material on a dome side of the glass sheet.

37. The method according to claim 36, further comprising removing a portion of the thin film material by photolithography.

38. The method according to claim 36, wherein the thin film material comprises a thin film transistor.

39. A thin film device comprising a glass sheet having a concavity, wherein the thin film device is disposed on a dome side of the glass sheet when the glass sheet is supported on a flat reference surface and wherein the glass sheet has a thickness between 0.2 mm and about 1.0 mm.

40. The thin film device according to claim 39, wherein the thin film device comprises a thin film transistor, a color filter, or an organic light emitting device.

41-44. (canceled)
